(19) United States
(12) Patent Application Publication
(10) Pub. No.: US 2014/0252606 A1
(43) Pub. Date: Sep. 11, 2014

(54) INTEGRATED CIRCUIT, MULTICORE PROCESSOR APPARATUS, AND METHOD FOR MANUFACTURING INTEGRATED CIRCUIT

(71) Applicant: Panasonic Corporation, Osaka (JP)

(72) Inventors: Takashi Morimoto, Osaka (JP); Takashi Hashimoto, Fukuoka (JP)

(21) Appl. No.: 14/351,429

(22) PCT Filed: Oct. 2, 2012
(86) PCT No.: PCT/JP2012/006285

§ 371 Date: Apr. 11, 2014

(30) Foreign Application Priority Data
Oct. 17, 2011 (JP) 2011-227918

(51) Int. Cl. H01L 25/065; H01L 23/00; H01L 23/48

(52) U.S. Cl. CPC H01L 25/0657; H01L 23/481; H01L 24/81; H01L 2225/06541; H01L 2225/06513
USPC 257/737; 438/107

(57) ABSTRACT

The preferred embodiment of the invention provides a three-dimensional integrated circuit at a suppressed fabrication cost as a whole while a common mask is used for fabricating chips, each of which constitutes the three-dimensional integrated circuit, and especially common area of buffers for bumps is used. The integrated circuit of the invention is an integrated circuit constituted by a plurality of chips laminated, including a first chip and a second chip both having the same layout for through silicon vias. The first chip is connected to a board via one or more first bumps, and further, the through silicon vias in a first number in the chip are connected to one first bump, the first number being a natural number of 2 or more.

### TECHNICAL FIELD

The present disclosure relates to a three-dimensional integrated circuit.

### BACKGROUND ART

An integrated circuit, in which a plurality of chips are laminated one on another, and then, are connected to each other via through silicon vias (hereinafter referred to as “TSVs”) or micro bumps, is generally referred to as a three-dimensional integrated circuit. The three-dimensional integrated circuit has been expected as a high-performance integrated circuit in order to achieve a high speed in a circuit, a broader band of data communications, and low electric power.

Incidentally, Patent Document 1 discloses a semiconductor integrated circuit having an output drive circuit, and further, Patent Document 2 discloses a memory controller in which the current drive capacity of an output buffer is variable.

### PRIOR ART DOCUMENTS

### Patent Documents

Patent Document 1: JP H02-125518 A
Patent Document 2: JP H10-050070 A

### SUMMARY OF INVENTION

### Problems to be Solved by the Invention

One non-limiting and exemplary embodiment provides a three-dimensional integrated circuit including chips fabricated via a common mask for fabricating chips at a suppressed fabrication cost.

### Means for Solving the Problem

The present invention is made for the purpose of solving the above problem. The integrated circuit according to the present disclosure is an integrated circuit including one or more chips that are laminated in the same layout, each of the chips comprising:

one or more through silicon vias and a wiring layer connected to the through silicon vias;

wherein, in the case of the chip being connected to a board, the chip is connected to the board via one or more first bumps, and further, the through silicon vias in a first number in the chip are connected to one first bump, the first number being a natural number of 2 or more; and

wherein, in the case of two of the chips being connected each other, when two of the chips are laminated while the ends of the through silicon vias and the wiring layer face each other, the positions of the ends of the through silicon vias match the positions of contact pads for the wiring layer.

### Effects of the Invention

According to the present disclosure, the drive capacity of a buffer for a TSV can be designed according to a bump for connecting chips, and further, a large drive capacity can be secured by use of a plurality of buffers in parallel to each other in connecting the chips to a bump for connecting a board. Consequently, it is unnecessary to secure a useless area for a larger buffer on the chip, and further, it is possible to satisfactorily achieve drive capacity for the bump for connecting the board. In other words, the single chip can cope with both the use for connecting the chips and the use for connecting the board. Thus, the present disclosure can achieve the common use of the chips constituting the three-dimensional integrated circuit, and therefore, can use a common mask for fabricating the chips, resulting in suppression of a fabrication cost.

### BRIEF DESCRIPTION OF DRAWINGS

FIG. 1(1) is a side cross-sectional view showing a three-dimensional integrated circuit according to a first preferred embodiment of the present disclosure; FIG. 1(2) is a view showing a TSV connected to a corresponding bump for connecting chips; and FIG. 1(3) is a view showing a plurality of TSVs connected to a corresponding bump for connecting a board.

FIG. 2(1) is a partial plan view showing the arrangement of the TSVs in a processor chip according to the first preferred embodiment of the present disclosure, wherein a broken line indicates the installation position of the bump for connecting the board at the lower surface of the processor chip; and FIG. 2(2) is a partial plan view showing the arrangement of the TSVs in the processor chip according to the first preferred embodiment of the present disclosure, wherein a broken line indicates the installation position of the bump for connecting the chips at the lower surface of the processor chip.

FIG. 3(1) is a partial plan view showing the arrangement of TSVs in a processor chip in a modification of the first preferred embodiment of the present disclosure, wherein a broken line indicates the installation range of a bump for connecting a board at the lower surface of the processor chip; and FIG. 3(2) is a partial plan view showing the arrangement of the TSVs in the processor chip in the modification of the first preferred embodiment of the present disclosure, wherein a broken line indicates the installation range of a bump for connecting chips at the lower surface of the processor chip.

FIG. 4 is a side cross-sectional view showing a three-dimensional integrated circuit in another modification of the first preferred embodiment of the present disclosure.

FIGS. 5(1) and 5(2) are partial plan views showing the arrangement of TSVs in a processor chip in the modification of the first preferred embodiment of the present disclosure.

FIG. 6(1) is a side cross-sectional view showing a three-dimensional integrated circuit according to a second preferred embodiment of the present disclosure; and FIG. 6(2) is a side cross-sectional view showing a three-dimensional integrated circuit in a modification of the second preferred embodiment of the present disclosure.

FIG. 7 is a diagram specifically illustrating the configuration of a chip in a three-dimensional integrated circuit according to a third preferred embodiment of the present disclosure.

FIG. 8 is a diagram illustrating another example of the configuration of a chip in a three-dimensional integrated circuit according to the third preferred embodiment of the present disclosure.

FIG. 9 is a diagram specifically illustrating the configuration of a chip in a three-dimensional integrated circuit according to a fourth preferred embodiment of the present disclosure;

FIGS. 10(1) to 10(3) show the configuration of a three-dimensional integrated circuit in the related art.

FIG. 11(1) is a view showing a TSV connected to a buffer whose drive capacity is designed with reference to a bump for connecting chips, and connected to a bump for connecting a board; and FIG. 11(2) is a view showing a TSV connected to a buffer whose drive capacity is designed with reference to a bump for connecting a board, and connected to a bump for connecting chips.

### MODE FOR CARRYING OUT THE INVENTION

### Story Behind Preferred Embodiments of Present Disclosure

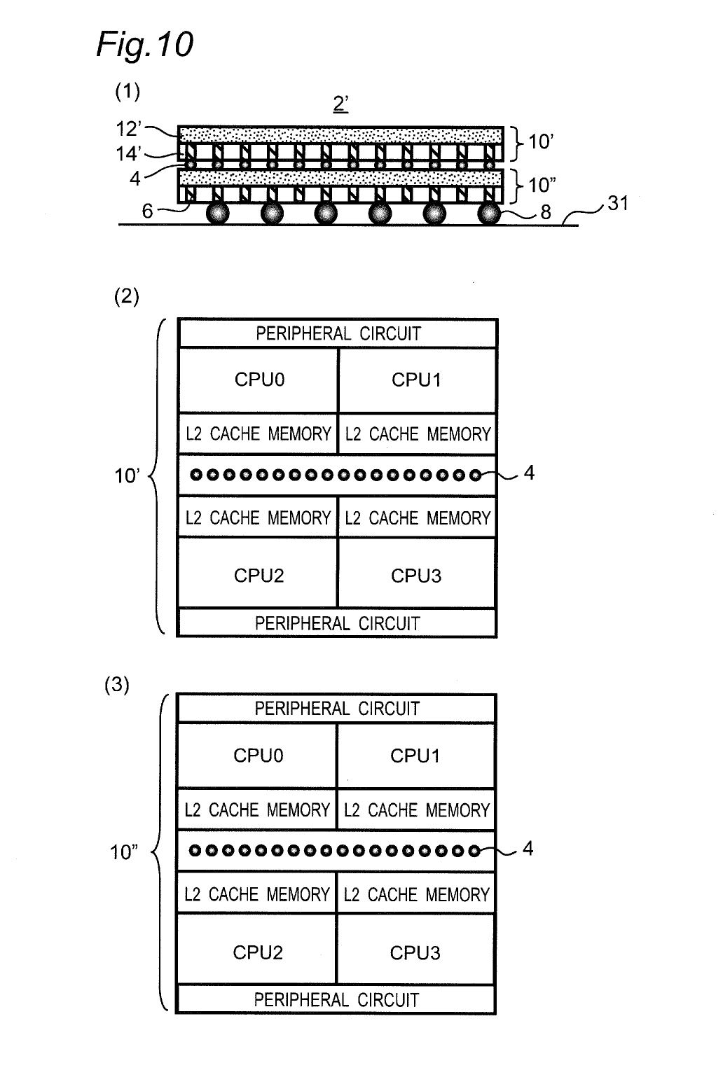

FIGS. 10(1) to 10(3) show an example of the configuration of a three-dimensional integrated circuit 2′ in the related art. A processor is mounted on the three-dimensional integrated circuit 2′ shown in FIGS. 10(1) to 10(3), wherein two chips (i.e., a first chip 10′ and a second chip 10″) having the same configuration are laminated one on another. FIG. 10(1) is a side cross-sectional view showing the three-dimensional integrated circuit 2′ in the related art; FIG. 10(2) is a circuit layout diagram illustrating the first chip 10′; and FIG. 10(3) is a circuit layout diagram illustrating the second chip 10″. As shown in FIGS. 10(1) to 10(3), each of the chips (i.e., the first chip 10′ and the second chip 10″) is provided with the same layout (i.e., the same configuration).

Each of the chips 10′ and 10″ includes mainly a processor core, level 1 cache memories (CPU0, CPU1, CPU2, and CPU3), and level 2 (L2) cache memories in view of a layout. Moreover, as shown in FIG. 10(1), each of the chips 10′ and 10″ includes a wiring layer 12′ and a transistor layer 14′, in which a plurality of TSVs 6 are arranged, in a laminated manner. The wiring layer 12′ is connected to the reverse (i.e., the lower surface) of the transistor layer 14′ via the TSVs 6.

Each of the chips is designed to be individually operated. Around the circuit parts of the first chip 10′ and the second chip 10″ are mounted peripheral circuits for accessing an external graphic circuit, an external memory, and the like. At the center of each of the chips 10′ and 10″ are arranged a plurality of bumps 4 for connecting chips. Each of the chips is connected to a chip at an upper layer via the bumps 4 for connecting the chips. Specifically, the second chip 10″ is connected to the first chip 10′ via the bumps 4 for connecting the chips. Here, the second chip 10″ as the lower chip is connected to a board (i.e., a circuit board) 31 via bumps 8 for connecting a board that are larger than the bumps 4 for connecting the chips.

The number of processor cores is varied by utilization of the configuration of the lamination shown in FIGS. 10(1) to 10(3), so that products of various grades can be designed. For example, it is possible to design a low-end integrated circuit constituted of a single chip and provided with four processor cores. In the same manner, it is possible to design a middle-range integrated circuit constituted of two chips and provided with eight processor cores or design a high-end integrated circuit constituted of four chips and provided with sixteen processor cores.

The chips, each having the same configuration, are laminated in the integrated circuit shown in FIGS. 10(1) to 10(3). That is to say, a fabricator can fabricate only one kind of chip in large amounts, thereby remarkably suppressing an increase in fabrication cost that has been conventionally induced by variations of chips including a chip fabricating mask or the like.

In each of the chips constituting the three-dimensional integrated circuit 2′ shown in FIGS. 10(1) to 10(3), the TSVs 6 achieve conduction from the wiring layer 12′ at the obverse of the chip to the reverse of the chip. Moreover, the TSVs 6 at the chip connected to the board 31, that is, the second chip 10″ are connected to the bumps 8 for connecting the board. The TSVs 6 are connected to the bumps 4 for connecting the chips at the chip laminated above a lowermost layer, that is, the first chip 10′.

In order to suppress the fabricating cost of the integrated circuit, it is desirable that the first chip 10′ and the second chip 10″ should have the same configuration. In this case, the TSVs formed at the chip need be designed in such a manner as to be connected to both of the bumps for connecting the chips and the bumps for connecting the board.

However, in this case, the designs of the bumps and buffers to be connected to the TSVs 6 have the following problems. As shown in FIGS. 10(1) to 10(3), fine bumps such as micro bumps are used as the bumps 4 for connecting the chips. Its diameter is about several μm, and further, its capacitance is several pF. Therefore, a great drive capacity is not required for a buffer to be connected to the bump 4 for connecting the chips. On the other hand, the diameter of the bump 8 for connecting the board is ten or more times the diameter of the bump 4 for connecting the chips, and its capacitance is increased according to the diameter.

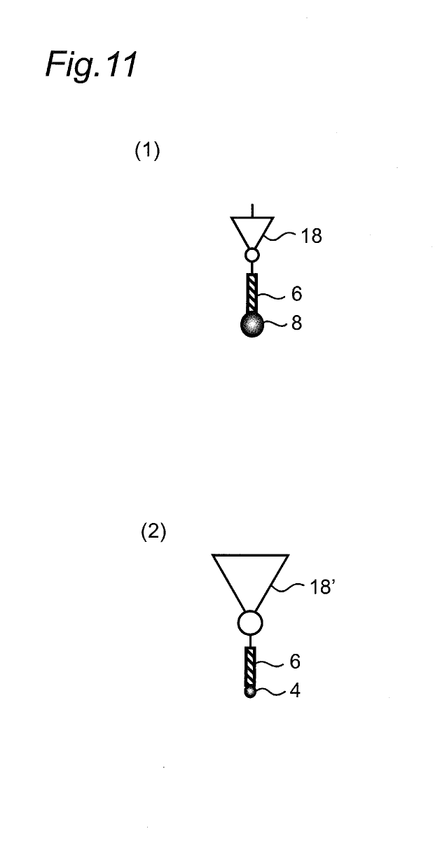

Therefore, if the drive capacity of the buffer to be connected to the TSV 6 is designed with reference to the bump 4 for connecting the chips, the buffer may be short of capacity for driving the bump 8 for connecting the board. FIG. 11(1) is a view showing the TSV 6 connected to a buffer 18 whose drive capacity is designed with reference to a bump 4 for connecting chips, and connected to the bump 8 for connecting the board.

In contrast, if the drive capacity of a buffer to be connected to the TSV 6 is designed with reference to the bump 8 for connecting the board, the capacity of the buffer becomes excessive in driving the bump 4 for connecting the chips. In other words, electric power may be excessively consumed. Moreover, a larger area for the buffer on the chip need be set. FIG. 11(2) is a view showing the TSV 6 connected to a buffer 18′ whose drive capacity is designed with reference to the bump 8 for connecting the board, and connected to the bump 4 for connecting the chips.

A method for solving the above-described problem is exemplified by buffer switching methods disclosed in Patent Document 1 and Patent Document 2. These are a method for preparing a plurality of buffers having different drive capacities and switching their output destinations via a selector switch, so as to dynamically change the drive capacity; and a method for controlling ON/OFF of a buffer for assisting drive capacity so as to dynamically change the drive capacity. However, in either method, it is necessary to provide a maximum drive capacity according to the bump for connecting the board as the performance of the buffer coping with a single bump. As a consequence, a region (i.e., an area) for the buffer on the chip becomes large, thereby affecting an area for other transistors or the like.

Preferred embodiments described below are adapted to solve the above-described problems, and provide a three-dimensional integrated circuit at a suppressed fabrication cost as a whole while a common mask is used for fabricating chips, each of which constitutes the three-dimensional integrated circuit.

Preferred embodiments will be described below with reference to the attached drawings.

### First Preferred Embodiment

### 1.1. Configuration of Three-Dimensional Integrated Circuit

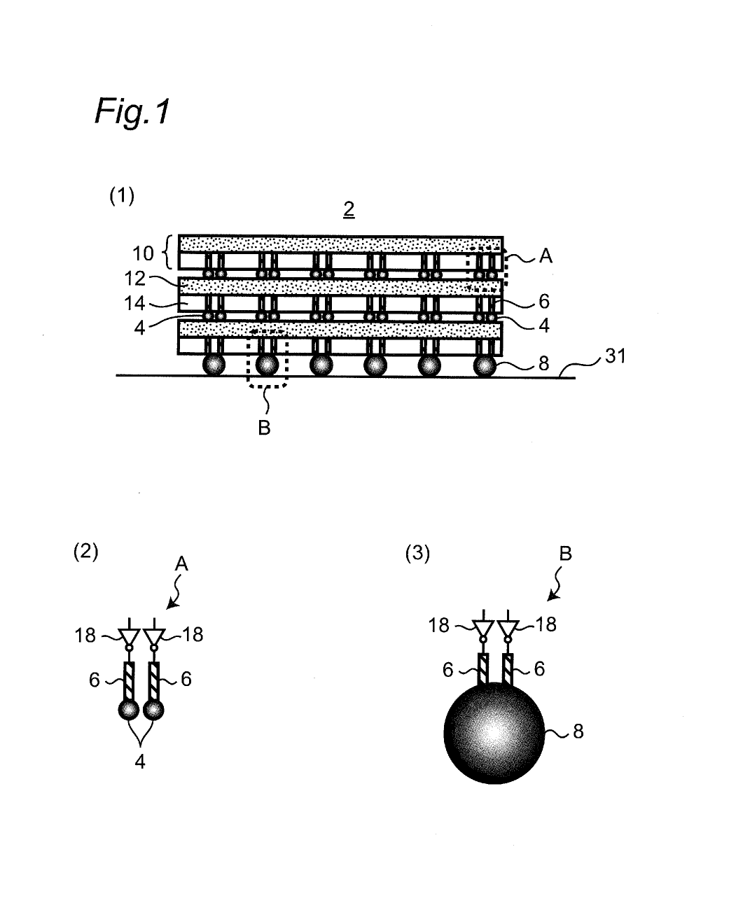

FIG. 1(1) is a side cross-sectional view showing a three-dimensional integrated circuit according to a first preferred embodiment. A three-dimensional integrated circuit 2 shown in FIG. 1(1) includes three chips 10 in lamination. Each of the three-layer chips 10 has the same configuration. Each of the chips 10 is formed by lamination of a wiring layer 12 and a transistor layer 14 having a plurality of TSVs (i.e., through silicon vias) 6 arranged thereon. The wiring layer 12 is connected to the reverse (i.e., the lower surface) of the transistor layer 14 via the TSVs 6.

The upper chip 10 and the lower chip 10 are connected via bumps 4 (hereinafter referred to as “bumps for connecting chips”). Moreover, the lowermost chip 10 is connected to a board (i.e., a circuit board) 31 via bumps 8 (hereinafter referred to as “bumps for connecting a board”).

In each of the chips 10 constituting the three-dimensional integrated circuit 2, the configurations of a TSV 6 and a buffer 18 for the TSV 6 are identical to each other. Specifically, the size, load capacitance, and the like of each of the TSVs 6 and each of the buffers 18 are the same between the chip 10 connected to the bumps 4 for connecting the chips and the chip 10 connected to the bumps 8 for connecting the board.

As shown in FIG. 1(2), one of the TSVs 6 is connected to one of the bumps 4 for connecting the chips corresponding to the TSV 6 in the case of the connection between the chips. A signal is driven to each of the TSVs 6 from the buffer 18 connected thereto. Incidentally, in the present preferred embodiment, the drive capacity of each of the buffers 18 is set with reference to a load capacitance on a precondition for the connection between the chips.

As shown in FIG. 1(3), the plurality of TSVs 6 are connected to a corresponding one out of the bumps 8 for connecting the board in the case of the connection between the chip 10 and the board 31. A circuit is set such that the same signal is driven to the plurality of TSVs 6 connected to one bump 8 for connecting the board. Since the buffer 18 is connected to each of the plurality of TSVs 6 connected to one bump 8 for connecting the board, the plurality of buffers 18 equipped with a satisfactory drive capacity can drive one bump 8 for connecting the board.

Here, a switch selector is disposed in front of the buffer 18 for driving the signal to the TSV 6 such that the signal for each of the TSVs 6 is designed to be driven to each of the TSVs 6 in the case of the connection between the chips: in contrast, the same signal is designed to be driven to the plurality of TSVs 6 connected to one bump 8 for connecting the board in the case of the connection between the chip 10 and the board 31. In other words, the switch by the switch selector sets the wiring such that the signals are driven to the TSVs 6, respectively, or the single signal is driven to the predetermined plurality of TSVs 6.

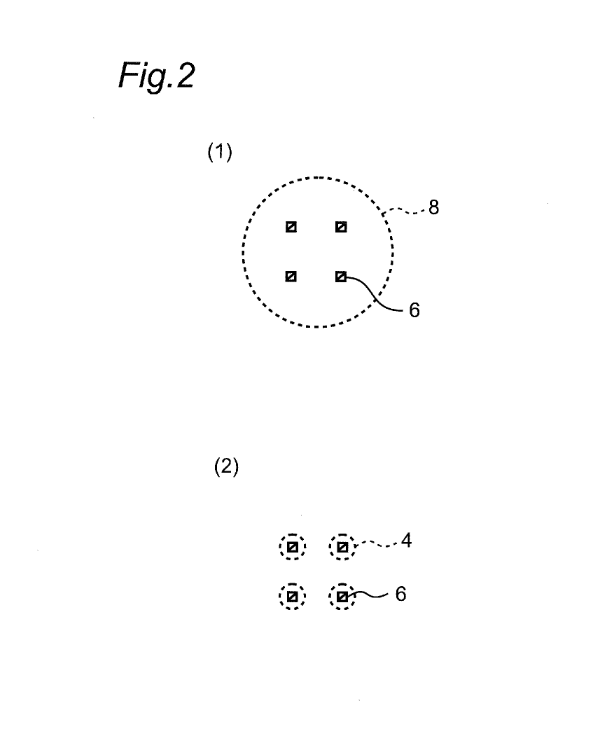

In the present preferred embodiment, it is preferable that the TSVs 6 should be laid out in such a manner as to be collected within a predetermined diametrical range in each of the chips 10 such that the plurality of TSVs 6 can be connected to the bump 8 for connecting the board. Such a predetermined diameter accords with the diameter of the bump 8 for connecting the board. FIGS. 2(1) and 2(2) show the arrangement of the TSVs in the chip 10 according to the present preferred embodiment. Broken lines indicate the installation ranges of the bump 8 for connecting the board (FIG. 2(1)) and the bump 4 for connecting the chips (FIG. 2(2)), respectively, at the lower surface of the chip 10. As shown in FIG. 2(1), it is preferable that the four TSVs 6 connected to one bump 8 for connecting the board should be arranged within the diametrical range of the bump 8 for connecting the board indicated by the broken line. Incidentally, each of the TSVs 6 is connected to the corresponding bump 4 for connecting the chips in the case of the connection between the chips, as shown in FIG. 2(2).

In FIGS. 2(1) and 2(2), for example, the diameter of the bump 8 for connecting the board is 100 μm and the diameter of the TSV is 7 μm. In order to connect the TSV to the bump 8 for connecting the board, the four TSVs 6 are laid out in arrangement within a diametrical range of 100 μm. The diameter of the bump 4 for connecting the chips is, for example, 10 μm. At this time, the bumps 4 for connecting the chips are connected to the TSVs 6, respectively.

Here, a contact pad, not shown, is disposed at each of the bumps 4 for connecting the chips connected to the lower end of each of the TSVs 6 in the upper laminated chip 10, on the wiring layer 12 in each of the chips 10 constituting the three-dimensional integrated circuit 2 shown in FIG. 1(1) so as to achieve proper connection. The upper chip 10 is properly laminated on the lower chip 10, so that the contact pad for the wiring layer 12 in the lower chip 10 is properly connected to the corresponding TSV 6 in the upper chip 10 and the corresponding bump 4 for connecting the chips.

### 1.2. Operation of Three-Dimensional Integrated Circuit

The plurality of chips 10 are laminated one on another, thereby building the three-dimensional integrated circuit 2. In the case of the connection between the chips in which the bump 4 for connecting the chips is used, one TSV 6 and one buffer 18 are connected to the bump 4 for connecting the chips. In contrast, in the case of the connection between the chip 10 and the board 31 in which the bump 8 for connecting the board is used, the plurality of TSVs 6 and the same number of buffers 18 as that of TSVs 6 are connected to one bump 8 for connecting the board.

As a consequence, one buffer 18 equipped with drive capacity required for the bump 4 for connecting the chips is used for communications of a signal between the chips 10 via the TSV 6. In other words, no buffer equipped with an excessive drive capacity is used for the bump 4 for connecting the chips. Thus, no useless area for disposing the buffer is provided in the chip 10.

The plurality of buffers 18 are used for communications of a signal between the chip 10 and the board 31 via the TSV 6 so as to achieve a drive capacity required for the bump 8 for connecting the board. Such a phenomenon does not occur that no buffer equipped with a satisfactory drive capacity required for the bump 8 for connecting the board is used.

### 1.3. Conclusion

In the present preferred embodiment, in the case of the connection between the chips in the three-dimensional integrated circuit 2 including the plurality of chips 10 in lamination, one TSV 6 is connected to the bump 4 for connecting the chips: in contrast, the plurality of TSVs 6 are connected to one bump 8 for connecting the board in the case of the connection between the board 31 and the chip 10.

With this configuration, the chips 10 having the same configuration can be used. In particular, the drive capacity of the buffer 18 for the TSV 6 can be designed according to the bump 4 for connecting the chips, and further, the plurality of buffers 18 each having a low drive capacity are used in parallel so as to secure a large drive capacity in the case of the connection to the bump 8 for connecting the board. In view of this, it is unnecessary to secure a useless area for a larger buffer on the chip 10, and further, it is possible to prevent an insufficient drive capacity for the bump 8 for connecting the board. In other words, no dedicated buffer need be provided for the bump 8 for connecting the board.

Thus, in the present preferred embodiment, it is possible to use a common mask for fabricating each of the processor chips 10 constituting the three-dimensional integrated circuit 2, so as to suppress a fabrication cost.

Incidentally, although one TSV 6 is connected to the bump 4 for connecting the chips whereas the two or four TSVs 6 are connected to the bump 8 for connecting the board in the preferred embodiment shown in FIGS. 1(1) to 2(2), the preferred embodiment is achieved also when the plurality of TSVs 6 are connected to the bump 4 for connecting the chips whereas the greater number of TSVs 6 are connected to the bump 8 for connecting the board. That is to say, even if the chips 10 and the three-dimensional integrated circuit 2 are configured in the above-described manner, the drive capacity of the buffer for the bump 8 for connecting the board becomes satisfactorily great whereas the drive capacity of the buffer for the bump 4 for connecting the chips cannot be greater than necessary, and further, it is unnecessary to secure an area for a large buffer on the chip 10.

### 1.4. Modifications

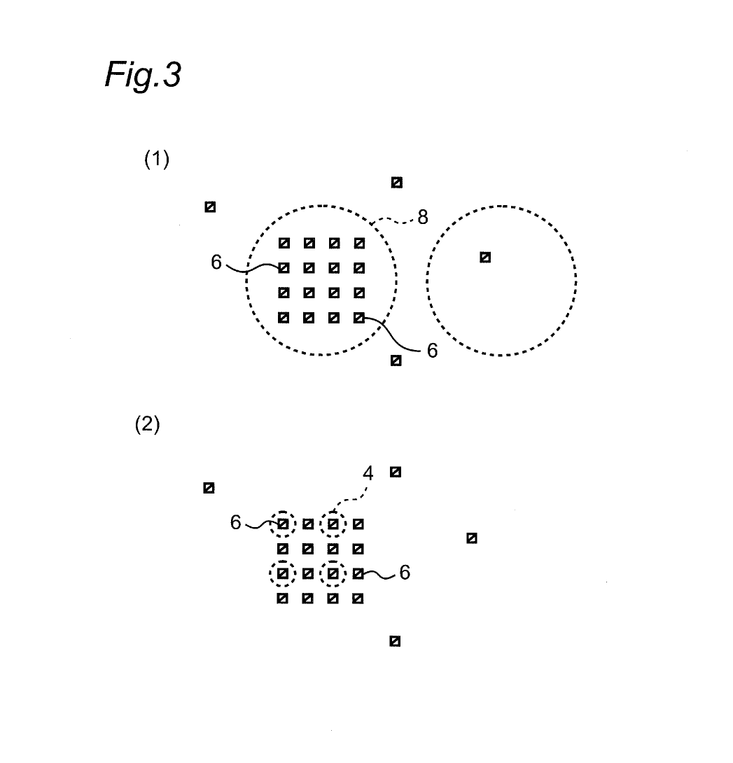

FIGS. 3(1) and 3(2) are views showing the arrangement of the TSVs in the chip 10 in a modification of the first preferred embodiment. Broken lines indicate the installation ranges of the bump 8 for connecting the board (FIG. 3(1)) and of the bump 4 for connecting the chips (FIG. 3(2)), respectively, at the lower surface of the chip 10.

Normally, each of the TSVs 6 has the same diameter. Therefore, in the case where a large current may possibly flow from the TSV 6 to the bump 8 for connecting the board, attention need be paid from the viewpoint of a design. This is because when a large current flows from the TSV 6 to the bump, electromigration occurs at the TSV 6, thereby raising a danger of a break. In order to avoid occurrence of such a phenomenon, 16 (i.e., satisfactorily many) TSVs 6 are arranged in concentration in such a manner as to be connected to a bump 8 for connecting a board in a chip 10 shown in FIG. 3(1). In this arrangement, when TSVs 6 are connected to bumps 4 for connecting chips, only some of the TSVs 6 may be used, as shown in FIG. 3(2).

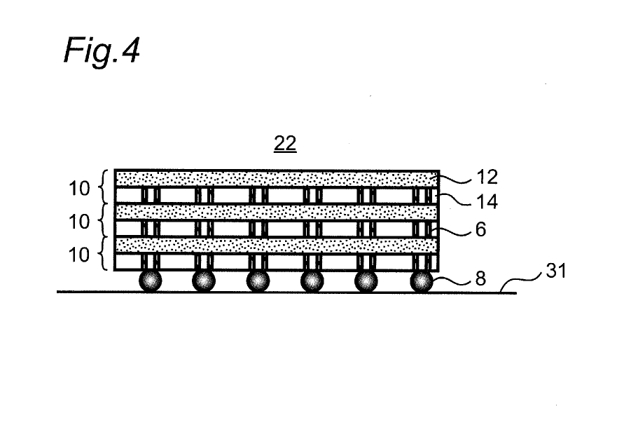

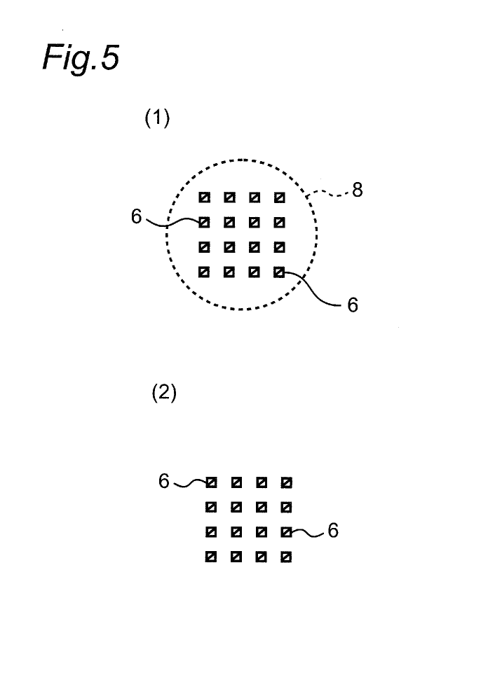

Additionally, FIG. 4 is a side cross-sectional view showing a three-dimensional integrated circuit 22 in another modification of the first preferred embodiment; and FIGS. 5(1) and 5(2) are views showing the arrangement of TSVs 6 in chips 10 in the modification. In the modification of the present preferred embodiment shown in FIG. 4, the TSVs 6 in an upper chip 10 are connected directly to a wiring layer 12 on a lower chip 10 in the case of connection between chips. In other words, a plurality of TSVs 6 (16 in FIG. 5(1)) in the chip 10 are connected to one bump 8 for connecting a board in the case of connection between the chip 10 and a board 31, as shown in FIG. 5(1): in contrast, TSVs 6 in the chip 10 are connected to the wiring layer 12 of the chip 10 not via a bump 4 for connecting chips in the case of connection between the chips 10, as shown in FIG. 5(2).

The wiring layer 12 of each of the chips 10 constituting the three-dimensional integrated circuit 22 shown in FIG. 4 is wired in such a manner as to be properly connected to the respective lower ends of the TSVs 6 in the chip 10 laminated above. The upper chip 10 is properly laminated on the lower chip 10, so that wirings of the wiring layer 12 in the lower chip 10 are properly connected to the lower ends of the corresponding TSVs 6 within the upper chip 10.

In the above-described manner, no bump is used in connecting the chips 10 in the three-dimensional integrated circuit shown in FIG. 4, thus reducing the volume of the three-dimensional integrated circuit 22 as a whole.

### Second Preferred Embodiment

Next, a description will be given of a three-dimensional integrated circuit according to a second preferred embodiment. The three-dimensional integrated circuit according to the second preferred embodiment is substantially similar to that according to the first preferred embodiment, and therefore, a difference therebetween will be mainly explained.

### 2.1 Configuration of Three-Dimensional Integrated Circuit

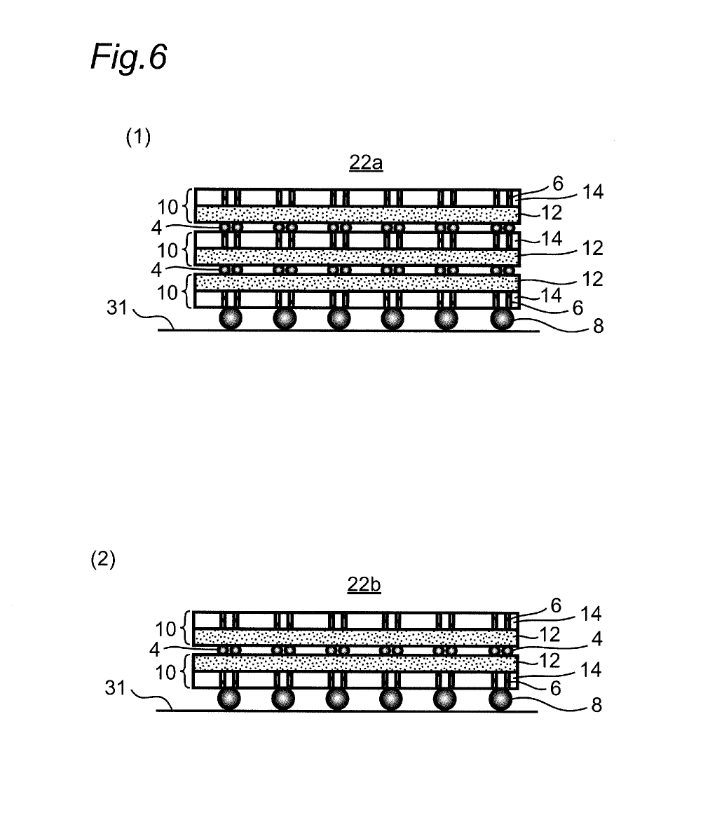

FIG. 6(1) is a side cross-sectional view showing a three-dimensional integrated circuit according to a second preferred embodiment. A three-dimensional integrated circuit 22a according to a second preferred embodiment shown in FIG. 6(1) includes three chips 10, that is, a lowermost chip 10, an intermediate chip 10, and an uppermost chip 10, in lamination. Each of the three-layer chips 10 has the same configuration. Each of the chips 10 is formed by lamination of a wiring layer 12 and a transistor layer 14 having a plurality of TSVs 6 arranged therein. The wiring layer 12 is connected to the reverse of the transistor layer 14 via the TSVs 6.

In the three-dimensional integrated circuit 22a according to the second preferred embodiment shown in FIG. 6(1), the lowermost chip 10 and the chip 10 laminated on the lowermost chip 10 (i.e., the intermediate chip) are laminated in such a manner that their wiring layers 12 face each other. The two wiring layers 12 facing each other are connected to each other via bumps 4 for connecting chips. In the respective wiring layers 12 of the chips constituting the three-dimensional integrated circuit 22a according to the second preferred embodiment, in the case where the wiring layers 12 face each other, a plurality of contact pads, not shown, for the bumps 4 for connecting the chips are arranged in such a manner that the wiring layers 12 facing each other are properly connected via the bumps 4 for connecting the chips.

The uppermost chip 10 and the chip 10 laminated on the uppermost chip 10 (i.e., the intermediate chip) are laminated in such a manner that the wiring layer 12 and the transistor layer 14 face each other. Specifically, the contact pads, not shown, at the wiring layer 12 in the uppermost chip 10 are connected to the ends of the TSVs 6 in the intermediate chip 10 via the bumps 4 for connecting the chips. As a consequence, the contact pads for the bumps 4 for connecting the chips at the wiring layer 12 in the chip 10 are arranged in such a manner as to achieve the connection also to the ends of the TSVs 6 in the other chip 10.

The TSVs 6 in the lowermost chip 10 are connected to a board 31 via bumps 8 for connecting a board.

The configurations of the TSV 6 and a buffer 18 for the TSV 6 are the same also in each of the chips 10 constituting the three-dimensional integrated circuit 22a according to the second preferred embodiment. That is to say, in each of the uppermost, intermediate, and lowermost chips 10, the size, load capacitance, and the like of each of the TSVs 6 and buffers 18 are the same. Therefore, when the lowermost chip 10 and the board 31 are connected to each other, the plurality of TSVs 6 are connected to the corresponding bumps 8 for connecting the board, respectively, as shown in FIG. 1(3). Since the buffer 18 is connected to each of the plurality of TSVs 6 connected to the bump 8 for connecting the board, one bump 8 for connecting the board is adapted to be driven by the plurality of buffers 18 equipped with a satisfactory drive capacity.

### 2.2. Operation of Three-Dimensional Integrated Circuit

In the second preferred embodiment shown in FIG. 6(1), the three chips 10 are laminated one on another, thereby building the three-dimensional integrated circuit 22a. In the case of the connection between the uppermost chip 10 and the intermediate chip 10 where the bumps 4 for connecting the chips are used, one TSV 6 and one buffer 18 in the intermediate chip 10 are connected to one bump 4 for connecting the chips. In contrast, in the case of the connection between the lowermost chip 10 and the board 31 in which the bump 8 for connecting the board is used, the plurality of TSVs 6 and the same number of buffers 18 as that of TSVs 6 in the lowermost chip 10 are connected to one bump 8 for connecting the board.

As a consequence, one buffer 18 equipped with a drive capacity required for the bump 4 for connecting the chips is used for communications of a signal between the uppermost chip 10 and the intermediate chip 10 via the TSVs 6. In other words, no buffer equipped with an excessive drive capacity is used for the bump 4 for connecting the chips. Thus, no useless area for disposing buffers need be provided at the chip 10.

The plurality of buffers 18 are used for communications of a signal between the lowermost chip 10 and the board 31 via the TSVs 6 so as to achieve a drive capacity required for the bump 8 for connecting the board. Such a phenomenon does not occur that no buffer equipped with a satisfactory drive capacity required for the bump 8 for connecting the board is used.

Moreover, the wiring layers 12 of both of the intermediate chip 10 and the lowermost chip 10 transmit a signal not via any TSVs in the case of communications of a signal only via the bumps 4 for connecting the chips between the intermediate chip 10 and the lowermost chip 10, thus achieving a high-speed processing.

### 2.3. Conclusion

In the three-dimensional integrated circuit 22a in the present preferred embodiment, in which the three chips 10 are laminated one on another, one TSV 6 is connected to one bump 4 for connecting the chips between the uppermost chip 10 and the intermediate chip 10. In the meantime, the plurality of TSVs 6 are connected to one bump 8 for connecting the board between the lowermost chip 10 and the board 31. Moreover, the wiring layers 12 of the intermediate chip 10 and the lowermost chip 10 are connected directly to each other only via the bumps 4 for connecting the chips between both of the chips 10.

With this configuration, the plurality of chips 10 having the same configuration can be used. In particular, the drive capacity of the buffer 18 for the TSV 6 can be designed according to the bump 4 for connecting the chips, and further, the plurality of the buffers 18 each having a low drive capacity are used in parallel so as to secure a large drive capacity in the case of the connection to the bump 8 for connecting the board. Additionally, the wiring layers 12 of the two chips 10 facing to each other are connected to each other only via the bumps 4 for connecting the chips, thus transmitting a signal at a high speed between the chips 10. In view of these, in the three-dimensional integrated circuit 22a, a special buffer for the bump 8 for connecting the board need not be provided, and further, a high-speed processing suitable for the use in a processor or the like can be achieved between the intermediate chip 10 and the lowermost chip 10.

Thus, in the present preferred embodiment, it is possible to use a common mask for fabricating each of the processor chips 10 constituting the three-dimensional integrated circuit 22a, so as to suppress a fabrication cost. Furthermore, the high-speed processing can be achieved in the three-dimensional integrated circuit 22a.

Incidentally, although FIG. 6(1) shows the three-dimensional integrated circuit 22a including the three chips 10, the three-dimensional integrated circuit in the present preferred embodiment may include much more chips 10. Moreover, as shown in FIG. 6(2), a three-dimensional integrated circuit 22b may include two chips 10. In this case, a lower chip 10 is connected to a board 31 via bumps 8 for connecting a board connected to a plurality of TSVs 6; respective wiring layers 12 of the lower chip 10 and an upper chip 10 face each other; and further, the wiring layers 12 facing each other are connected to each other via bumps 4 for connecting the chips.

### Third Preferred Embodiment

A specific constitutional example of the chip in the three-dimensional integrated circuit described by way of the first preferred embodiment will be described in the present preferred embodiment.

### 3.1. Configuration of Chip

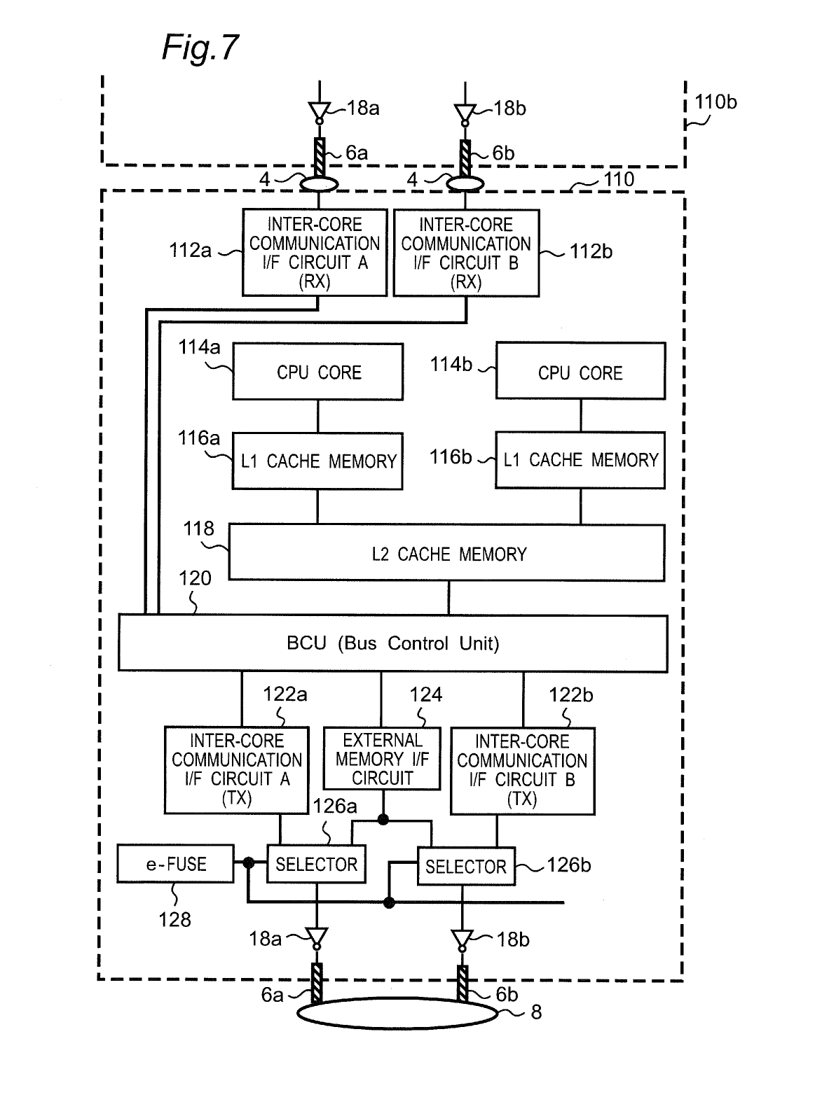

FIG. 7 is a diagram specifically illustrating the configuration of one chip in a three-dimensional integrated circuit in a third preferred embodiment. FIG. 7 illustrates the block configuration of the inside of a lowermost chip 110 in the integrated circuit. FIG. 7 illustrates mainly an inter-CPU core communication I/F (interface) circuit, an external memory I/F circuit, and circuits relevant thereto.

The chip 110 illustrated in FIG. 7 is a processor chip that is lowermost laminated and connected to an external memory, not illustrated. Here, although not illustrated, one or more processor chips 110b having the same configuration are laminated on the chip 110.

Each of the processor chips 110 includes two CPU cores 114a and 114b, two level 1 cache memories 116a and 116b, and a level 2 cache memory 118, as illustrated in FIG. 7. Each of the CPU cores 114a and 114b communicates with CPU cores and cache memories in other processor chips 110 via a BCU (abbreviating a bus control unit) 120. Moreover, the CPU cores 114a and 114b inside of the processor chip 110 access an external memory via the BCU 120. Incidentally, an external memory I/F circuit 124 is a circuit unit for communicating with an external memory.

Inter-core communication I/F circuits (RXs) 112a and 112b are circuit units for communicating with the processor chip 110b laminated on the chip 110. Inside of these circuits are included communication protocol processing circuits for passing data between CPU cores and the like. A communication protocol may be a communication protocol that is originally determined or a versatile protocol such as a PCI. According to a communication method, the inter-core communication I/F circuits (RXs) 112a and 112b include a synchronizer circuit for receiving an asynchronous signal and the like. Here, the inter-core communication I/F circuits (TXs) 112a and 112b are circuit units for communicating with the processor chip 110 laminated under.

The inter-core communication I/F circuits (RXs) (TXs) are circuits to be used for two main purposes: one is for communications between the CPU cores provided between different processor chips 110, and further, the other is for access to the external memory from the CPU core in the processor chip 110b laminated above. Since the external memory is connected to the lowermost processor chip 110, data need be passed to the lowermost processor chip 110 connected to the external memory in order to access the external memory from the CPU core inside of the processor chip 110 laminated above. At this time, the inter-core communication I/F circuits (RXs) (TXs) are used.

Under inter-core communication I/F circuits (TXs) 122a and 122b and the external memory I/F circuit 124 are arranged selectors 126a and 126b and an e-fuse 128. The selectors 126a and 126b are circuits for setting a choice [1] or [2], as follows:

[1] connecting the inter-core communication I/F circuit (TX) 122a to one buffer 18a and one TSV 6a, and further, connecting the inter-core communication I/F circuit (TX) 122b to another buffer 18b and another TSV 6b; and

[2] connecting the external memory I/F circuit 124 to the two buffers 18a and 18b and the two TSVs 6a and 6b.

Out of the above-described choices [1] and [2], the selectors 126a and 126b set the choice [1] in the case of the connection between the chips: in contrast, they set the choice [2] in the case of the connection between the board 31 and the chip 110. Incidentally, in the processor chip 110 illustrated in FIG. 7, the choice [2] is set by the selectors 126a and 126b.

A description will be given of the selectors 126a and 126b in the chip 110 in the three-dimensional integrated circuit in the third preferred embodiment illustrated in FIG. 7.

The processor chip 110 illustrated in FIG. 7 is configured such that one TSV 6 is connected to a bump 4 for connecting chips whereas a plurality of TSVs 6 are connected to a bump 8 for connecting a board. In view of this, the same signal need be driven to the plurality of TSVs 6 connected to the single bump 8 for connecting the board. Here, the drive of the same signal to the plurality of TSVs 6 connected to the single bump 8 for connecting the board is achieved by the setting by the selectors 126a and 126b.

Specifically, the processor chip 110 illustrated in FIG. 7 is interposed between the chip 110b and the board 31, and further, the two TSVs 6a and 6b are connected to the bump 8 for connecting the board. Here, the selectors 126a and 126b set the choice such that the two TSVs 6 and the two buffers 18 drive a signal from the external memory I/F circuit 124 to the bump 8 for connecting the board. In this manner, the single signal is driven to the bump 8 for connecting the board via the two buffers 18. In other words, the signal is driven by the buffers having a large drive capacity.

A signal for setting the choice by the selectors 126a and 126b is written by the e-fuse 128. The combination of the selectors and the e-fuse may be replaced with the use of a non-volatile storage device. Alternatively, a storage device, in which an initial value is written through an external terminal, may be used.

Here, when the same processor chip 110 is connected (laminated) under the processor chip 110 illustrated in FIG. 7, the choice by the selector 124 is set such that a signal from the inter-core communication I/F circuit (TX) 122a is driven to the bump 4 for connecting the chips via one buffer 18a and one TSV 6a, and simultaneously, a signal from the inter-core communication I/F circuit (TX) 122b is driven to the other bump 4 for connecting the chips via another buffer 18b and another TSV 6b. A pair of buffers 18a and 18b, a pair of TSVs 6a and 6b, and bumps 4 for connecting chips, all of which are illustrated at the upper section of the processor chip 110 illustrated in FIG. 7, show a connection mode in which, as the upper layer, the same processor chip 110b is connected to (laminated on).

### 3.2. Another Example of Chip

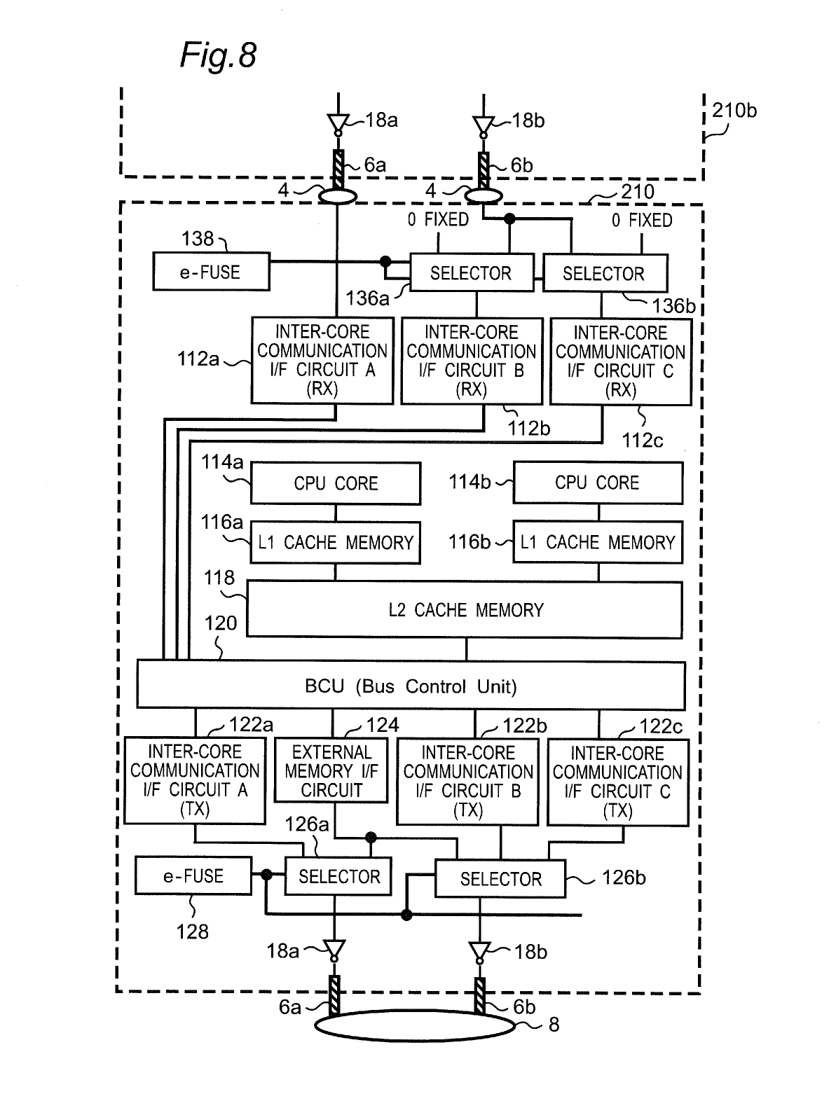

Although the selectors 126a and 126b immediately before the buffers 18a and 18b, respectively, choose one of the two options (the choices [1] and [2]) in the chip 110 in the three-dimensional integrated circuit in the third preferred embodiment illustrated in FIG. 7, the selectors may choose one out of three options. FIG. 8 is a diagram illustrating another example of the configuration of a chip in a three-dimensional integrated circuit in the third preferred embodiment. Selectors 126a and 126b illustrated in FIG. 8 are circuits for setting a choice [2-1], [2-2], or [2-3], as follows:

[2-1] connecting an inter-core communication I/F circuit (TX) 122a to one buffer 18 and one TSV 6, and further, connecting an inter-core communication I/F circuit (TX) 122b to another buffer 18 and another TSV 6;

[2-2] connecting the inter-core communication I/F circuit (TX) 122a to one buffer 18 and one TSV 6, and further, connecting an inter-core communication I/F circuit (TX) 122c to another buffer 18 and another TSV 6; and

[2-3] connecting the external memory I/F circuit 124 to two buffers 18 and two TSVs 6.

Here, selectors 136a and 136b disposed at the upper section of a chip 210 also are circuits for setting a choice [3-1] or [3-2], as follows:

[3-1] connecting one bump 4 for connecting chips to an inter-core communication I/F circuit (RX) 112b; and

[3-2] connecting one bump 4 for connecting chips to an inter-core communication I/F circuit (RX) 112c.

### Fourth Preferred Embodiment

A specific constitutional example of a chip in the three-dimensional integrated circuit described by way of the first preferred embodiment will be described also in the present preferred embodiment.

### 4.1. Configuration of Chip

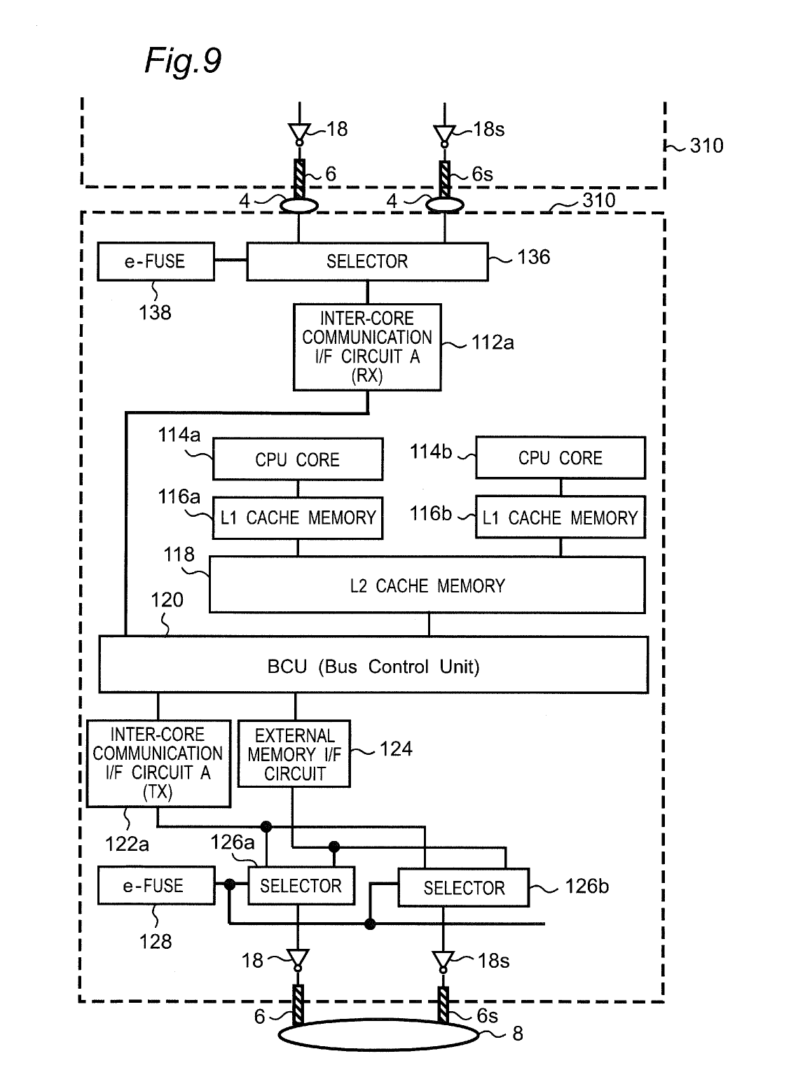

FIG. 9 is a diagram specifically illustrating the configuration of one chip in a three-dimensional integrated circuit in a fourth preferred embodiment. FIG. 9 also illustrates the block configuration of the inside of a lowermost chip 310 in the integrated circuit. The processor chip 310 illustrated in FIG. 9 uses some of TSVs 6 in the processor chip 310 disposed in an upper section as a redundant relief TSV. Here, processor-related parts such as a CPU core in the block configuration illustrated in FIG. 9 are the same as those in the block configuration illustrated in FIG. 7. The same component parts are designated by the same reference numerals, and therefore, their explanation will be omitted.

In general, in the case of connection between chips, a bump 4 for connecting chips is fine, thereby inducing deficient connection. As a consequence, the measures of redundant relief may be adopted such that the chip can be shipped as a good product even if deficient connection occurs. The redundant relief in terms of a chip signifies arranging a plurality of spare TSVs (hereinafter referred to as “redundant relief TSVs”) around normal TSVs (hereinafter referred to as “normal TSVs”).

In the three-dimensional integrated circuit illustrated in FIG. 9, the present preferred embodiment is applied to a redundant relief TSV. First, in the circuit illustrated in FIG. 9, a lower right TSV (6s) in a processor chip 310 located above a processor chip 310 illustrated in the center of FIG. 9 holds for a redundant relief TSV with respect to a normal TSV 6 located on the left.

The circuit illustrated in FIG. 9 is designed such that if there is deficient connection between the normal TSV 6 and the bump 4 for connecting the chips, the normal TSV 6 is switched to the redundant relief TSV 6s disposed around the normal TSV 6 as a TSV for transmitting a signal to the outside of the chip. In order to achieve this configuration, a selector 136 is provided for setting the choice between the normal TSV 6 and the redundant relief TSV 6s inside of the processor chip 310 on a signal reception side. In general, it is determined in an item confirmation test on a chip after lamination whether or not there is deficient connection between the normal TSV 6 and the bump 4 for connecting the chips. Therefore, an e-fuse 138 sets the choice of the selector 136 before the shipment of a three-dimensional integrated circuit.

In the meantime, when the processor chip 310 is connected to a board 31 via a bump 8 for connecting a board, deficient connection seldom occurs since the bump 8 for connecting the board is considerably large. In other words, a redundant relief TSV is seldom needed at the time of the connection of the board. Utilizing this feature, the circuit is designed such that both of the normal TSV 6 and the redundant relief TSV 6s are connected to the bump 8 for connecting the board so as to drive a single signal. With this configuration, the two TSVs, that is, the normal TSV 6 and the redundant relief TSV 6s, drive the same signal from two buffers 18 to the bump 8 for connecting the board, and therefore, drive the signal by use of the buffers having a large drive capacity.

Here, selectors 126a and 126b disposed at a lower section of the processor core 310 together with an e-fuse 128 are circuits for setting a choice [4-1] or [4-2], as follows:

[4-1] connecting an inter-core communication I/F circuit (TX) 122a to the buffer 18 and the normal TSV 6 and to a buffer 18s and the redundant relief TSV 6s; and

[4-2] connecting an external memory I/F circuit 124 to the buffer 18 and the normal TSV 6 and to the buffer 18s and the redundant relief TSV 6s.

Specifically, in the case where the processor chip 310 is connected under the other processor chip 310, the choice [4-1] is set. At this time, the bumps 4 for connecting the chips are connected to the normal TSV 6 and the redundant relief TSV 6s, respectively, and therefore, the redundant relief TSV 6s functions as means for the purpose of original redundant relief. In contrast, in the case where the board 31 is connected under the processor chip 310, the choice [4-2] is set. At this time, the normal TSV 6 and the redundant relief TSV 6s are connected to the bump 8 for connecting the board, and therefore, the two buffers 18 connected to the normal TSV 6 and the redundant relief TSV 6s, respectively, are adapted to drive the same signal.

### Other Preferred Embodiments

In the three-dimensional integrated circuits in the first to fourth preferred embodiments, the processor chips having the same configuration are laminated. However, the idea of these preferred embodiments is applicable to a three-dimensional integrated circuit having other chips laminated thereon. The chip may be an FPGA (abbreviating a Field-Programmable Gate Array) or a system LSI for a television or a recorder.

Moreover, the number of laminated chips, the diameter of the bump or the TSV, and the like are not limited to those in the above-described preferred embodiments, and therefore, other numbers or sizes may be applied.

Although the plurality of chips having the same configuration are laminated in the three-dimensional integrated circuit illustrated in FIGS. 1 to 4, the idea of the above-described preferred embodiment is applicable to a three-dimensional integrated circuit, in which the chip 10 connected to the board 31 and the uppermost chip 10 are identical to each other whereas chips having different configurations are held therebetween. That is to say, a common mask for chip fabrication can be used so as to suppress a fabrication cost at the lowermost chip 10 and the uppermost chip 10 in such a three-dimensional integrated circuit. In the same manner, the idea of the above-described preferred embodiment is applicable to a three-dimensional integrated circuit, in which the chip 10 connected to the board 31 and the chip 10 held between a plurality of intermediate laminated chips are identical to each other whereas other chips have different configurations.

### Abstract of One Aspect According to the Invention

(1) An integrated circuit in accordance with the first aspect of the invention includes one or more chips that are laminated in the same layout. Each of the chips comprises:

one or more through silicon vias and a wiring layer connected to the through silicon vias.

When two of the chips are laminated while the ends of the through silicon vias and the wiring layer face each other, the positions of the ends of the through silicon vias match the positions of contact pads for the wiring layer.

When two of the chips are laminated while the wiring layers face each other, the positions of the contact pads for one of the wiring layers match the positions of the contact pads for the other wiring layer.

And the chip is connected to a board via one or more first bumps, and further, the through silicon vias in a first number in the chip are connected to one first bump, the first number being a natural number of 2 or more.

With this configuration, the drive capacity of a buffer for a TSV can be designed according to a bump for connecting chips, and further, a large drive capacity can be secured by using a plurality of buffers in parallel to each other in connecting the chips to a bump for connecting a board. Consequently, it is unnecessary to secure a useless area for a larger buffer on the chip, and further, it is possible to satisfactorily achieve drive capacity for the bump for connecting the board. In other words, the single chip can cope with both the use for connecting the chips and the use for connecting the board. Thus, the present invention can achieve the common use of the chips constituting the three-dimensional integrated circuit, and therefore, can use a common mask for fabricating the chips, resulting in suppression of a fabrication cost.

(2) An integrated circuit in accordance with the second aspect of the invention may be the integrated circuit in accordance with the first aspect of the invention wherein the plurality of chips are laminated one on another.

With this configuration, it becomes possible to use a common mask for fabricating each of a plurality of chips laminated and constituting the three-dimensional integrated circuit, so as to suppress a fabrication cost.

(3) An integrated circuit in accordance with the third aspect of the invention may be the integrated circuit in accordance with the first aspect of the invention, wherein the chip is connected to another laminated chip via one or more second bumps; and

wherein at this time, the through silicon vias in a second number in the chip are connected to one second bump;

the second number being a natural number smaller than the first number.

With this configuration, it becomes possible to use a common mask for fabricating each of more than three chips laminated and constituting the three-dimensional integrated circuit, so as to suppress a fabrication cost.

(4) An integrated circuit in accordance with the fourth aspect of the invention may be the integrated circuit in accordance with the third aspect of the invention, wherein in the chip, the plurality of through silicon vias are arranged and collected within the diameter of the first bump.

With this configuration, in the three-dimensional integrated circuit constituted by a plurality of chips laminated, it becomes possible to avoid breaks of the TSVs due to electromigration.

(5) An integrated circuit in accordance with the fifth aspect of the invention may be the integrated circuit in accordance with the fourth aspect of the invention, wherein the through silicon vias in the first number connected to the one first bump include one or more through silicon vias for redundant relief.

With this configuration, in the three-dimensional integrated circuit constituted by a plurality of chips laminated, it becomes possible to incorporate properly one or more through silicon vias for redundant relief.

(6) An integrated circuit in accordance with the sixth aspect of the invention may be the integrated circuit in accordance with the third aspect of the invention, wherein the through silicon vias in the chip are connected directly to the wiring layer on another laminated chip not via bumps.

With this configuration, the whole volume of the three-dimensional integrated circuit constituted by a plurality of chips laminated can be reduced.

(7) An integrated circuit in accordance with the seventh aspect of the invention includes a plurality of chips that are laminated in the same layout. Each of the chips comprises:

one or more through silicon vias and a wiring layer connected to the through silicon vias.

When two of the chips are laminated while the ends of the through silicon vias and the wiring layer face each other, the positions of the ends of the through silicon vias match the positions of contact pads for the wiring layer.

When two of the chips are laminated while the wiring layers face each other, the positions of the contact pads for one of the wiring layers match the positions of the contact pads for the other wiring layer.

At the time of connection to the board, the chip is connected to a board via one or more first bumps, and further, the through silicon vias in a first number in the chip are connected to one first bump, the first number being a natural number of 2 or more.

At the time of connection to another laminated chip, the chip is connected to another laminated chip via one or more second bumps. The through silicon vias in a second number in the chip are connected to one second bump; the second number being a natural number smaller than the first number.

And the chip further includes one or more setting unit for setting wiring of one or more input circuits with respect to each of the through silicon vias such that the through silicon vias connected to the same bump output a single signal.

With this configuration, it becomes possible to use a common mask for fabricating each of a plurality of chips laminated and constituting the three-dimensional integrated circuit and to set wiring of circuits at the time of integrating chips, so as to suppress a fabrication cost.

(8) A multiple core processor apparatus in accordance with the eighth aspect of the invention may be a multiple core processor apparatus including the integrated circuit according to the second aspect of the invention,

wherein the chip comprises a processor core, a level 1 cache memory, a level 2 cache memory, and peripheral circuits for accessing external circuits.

With this configuration, it becomes possible to use a common mask for fabricating each of a plurality of chips constituting the multiple core processor apparatus, so as to suppress a fabrication cost.

(9) An fabricating method for an integrated circuit in accordance with the tenth aspect of the invention is the fabricating method comprising the steps of:

forming a laminated chip including one or more through silicon vias and a wiring layer connected to the through silicon vias, wherein when two of the chips are laminated while the ends of the through silicon vias and the wiring layer face each other, the positions of the ends of the through silicon vias match the positions of contact pads for the wiring layer and when two of the chips are laminated while the wiring layers face each other, the positions of the contact pads for one of the wiring layers match the positions of the contact pads for the other of the wiring layers; and

connecting the through silicon vias in a first number being a natural number of 2 or more to one first bump connected to a board in the chip.

With this configuration, it becomes possible to use a common mask for fabricating each of a plurality of chips laminated and constituting the three-dimensional integrated circuit, so as to suppress a fabrication cost.

### INDUSTRIAL APPLICABILITY

The present invention is effectively applicable to the three-dimensional integrated circuit configured by lamination of the processor chips, the FPGAs, or the system LSIs one on another.

### DESCRIPTION OF REFERENCE CHARACTERS

2 three-dimensional integrated circuit
4 bump for connecting chips
6 TSV (through silicon via)
8 bump for connecting board
10, 110, 210, 310 processor chip
12 wiring layer
14 transistor layer
18 buffer
31 board (circuit board)

1.-26. (canceled)

27. An integrated circuit including a board and a first chip connected to the board via bumps for connecting the board, the first chip comprising:
a plurality of through silicon vias;
a wiring layer connected to the plurality of through silicon vias; and
a plurality of buffers, each connected to each of the plurality of through silicon, driving signals to the through silicon vias,
wherein the through silicon vias in a first number being a natural number of 2 or more are connected to the one bump for connecting the board; and
wherein same signals are driven to the through silicon vias in the first number via the buffers each connected to each of the through silicon vias.

28. The integrated circuit according to claim 27,
wherein the first circuit further comprises a setting circuit which selects whether that different signals are driven to through silicon vias, respectively, or that a single signal is driven to the predetermined plurality of through silicon vias; and
wherein in the setting circuit same signal is designed to be driven to through silicon vias in the first number.

29. The integrated circuit according to claim 27,
wherein one of the buffers is short of capacity for driving the bump for connecting the board, and by gathering plurally the buffers has capacity for driving the bump for connecting the board.

30. The integrated circuit according to claim 27,
further including a second chip which has the same layout of the first chip,
wherein the first chip and the second chip are laminated such that the wiring layer of the first chip and the wiring layer of the second chip face each other.

31. The integrated circuit according to claim 30,
wherein, in the layout of the first chip and in the layout of the second chip, the positions of contact pads for the wiring layer of the first chip match the positions of contact pads for the wiring layer of the second chip.

32. The integrated circuit according to claim 30,
wherein the wiring layer of the first chip and the wiring layer of the second chip are connected via bumps for connecting chips.

33. The integrated circuit according to claim 27,
further including a second chip which has the same layout of the first chip,
wherein the first chip and the second chip are laminated such that the wiring layer of the first chip and the ends of the through silicon vias of the second chip face each other.

34. The integrated circuit according to claim 33,
wherein, in the layout of the first chip and in the layout of the second chip, the positions of contact pads for the wiring layer of the first chip match the positions of the ends of the through silicon vias of the second chip.

35. The integrated circuit according to claim 33,
wherein the wiring layer of the first chip and the ends of the through silicon vias of the second chip are connected via bumps for connecting chips; and
wherein the through silicon vias in a second number being a natural number smaller than the first number are connected to the one bump for connecting chips.

36. The integrated circuit according to claim 33,
wherein the wiring layer of the first chip and the ends of the through silicon vias of the second chip are connected not via bumps for connecting chips.

37. The integrated circuit according to claim 27,
wherein the through silicon vias in the first number connected to the one bump for connecting the board include one or more through silicon vias for redundant relief.

38. The integrated circuit according to claim 27,
wherein in the first chip, a plurality of through silicon vias are arranged and collected within the diameter of the bump for connecting the board.

39. A chip comprising:
a plurality of through silicon vias;
a wiring layer connected to the plurality of through silicon vias;
a plurality of buffers, each connected to each of the plurality of through silicon, driving signals to the through silicon vias; and
a setting circuit which selects whether that different signals are driven to through silicon vias, respectively, or that a single signal is driven to the predetermined plurality of through silicon vias.
